(19) United States
(12) Patent Application Publication
(10) Pub. No.: US 2025/0226245 A1
(43) Pub. Date: Jul. 10, 2025

(54) SUBSTRATE PROCESSING SYSTEM

(71) Applicant: SAMSUNG ELECTRONICS CO., LTD., Suwon-si (KR)

(72) Inventors: Tae Kun KIM, Suwon-si (KR); Hyeok Jae KWON, Suwon-si (KR); Ki Hun LEE, Suwon-si (KR); Eui Seok KUM, Suwon-si (KR); Byeong Hee KIM, Suwon-si (KR); Byeong Eon LEE, Suwon-si (KR); Yo Hwan JOO, Suwon-si (KR)

(73) Assignee: SAMSUNG ELECTRONICS CO., LTD., Suwon-si (KR)

(21) Appl. No.: 18/908,344

(22) Filed: Oct. 7, 2024

(30) Foreign Application Priority Data
Jan. 4, 2024 (KR) 10-2024-0001681

(51) Int. Cl. H01L 21/67; C23C 16/52; H01L 21/02; H01L 21/677; H01L 21/68

(52) U.S. Cl. CPC H01L 21/67201; C23C 16/52; H01L 21/02043; H01L 21/67742; H01L 21/68

(57) ABSTRACT

A substrate processing system includes a loadlock chamber configured to receive a front opening unified pod (FOUP) that stores a plurality of wafers, a process chamber in which a semiconductor process is configured to be performed on the plurality of wafers, a transfer robot configured to transfer the plurality of wafers from the loadlock chamber to the process chamber, and a controller configured to determine a number of the plurality of wafers in the loadlock chamber and control cleaning of the process chamber based on the determined number of the plurality of wafers, where the plurality of wafers include a plurality of unprocessed wafers in the loadlock chamber, and a plurality of in-process wafers, the plurality of in-process wafers being removed from the loadlock chamber and transferred to the process chamber.

### CROSS-REFERENCE TO RELATED APPLICATION

This application is based on and claims priority to Korean Patent Application No. 10-2024-0001681, filed on Jan. 4, 2024, in the Korean Intellectual Property Office, the disclosure of which is incorporated by reference herein in its entirety.

### BACKGROUND

Example embodiments of the disclosure relate to a substrate processing system.

To manufacture a semiconductor device, a substrate may be processed through various processes such as photolithography, etching, ashing, ion implantation, thin film deposition, and cleaning to form a desired pattern on the substrate.

In order to perform the above semiconductor processes accurately and precisely, by-products deposited in a chamber where the various semiconductor processes are performed should be periodically removed via cleaning.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing system for manufacturing a semiconductor device with improved performance and reliability.

Additional aspects will be set forth in part in the description which follows and, in part, will be apparent from the description, or may be learned by practice of the presented embodiments.

According to an aspect of an example embodiment, a substrate processing system may include a loadlock chamber configured to receive a front opening unified pod (FOUP) that stores a plurality of wafers, a process chamber in which a semiconductor process is configured to be performed on the plurality of wafers, a transfer robot configured to transfer the plurality of wafers from the loadlock chamber to the process chamber, and a controller configured to determine a number of the plurality of wafers in the loadlock chamber and control cleaning of the process chamber based on the determined number of the plurality of wafers, where the plurality of wafers include a plurality of unprocessed wafers in the loadlock chamber, and a plurality of in-process wafers, the plurality of in-process wafers being removed from the loadlock chamber and transferred to the process chamber, based on a number of the plurality of unprocessed wafers being smaller than or equal to a preset value, the controller is configured to initiate cleaning of the process chamber after completion of the semiconductor process on both the plurality of unprocessed wafers and the plurality of in-process wafers, and based on the number of the plurality of unprocessed wafers being greater than the preset value, the controller is configured to initiate cleaning of the process chamber after completion of the semiconductor process on only the plurality of in-process wafers.

According to an aspect of an example embodiment, a substrate processing system may include a first loadlock chamber configured to receive a first FOUP that stores a plurality of first wafers, a first process chamber in which a first semiconductor process is configured to be performed on the plurality of first wafers, a second loadlock chamber configured to receive a second FOUP that stores a plurality of second wafers, a second process chamber in which a second semiconductor process is configured to be performed on the plurality of second wafers, a transfer robot configured to transfer the plurality of first wafers to the first process chamber and transfer the plurality of second wafers to the second process chamber, and a controller configured to determine a number of the plurality of first wafers in the first loadlock chamber and a number of the plurality of second wafers in the second loadlock chamber, and control cleaning of the first process chamber and the second process chamber based on the determined number of the plurality of first wafers and the determined number of the plurality of second wafers, where the plurality of first wafers include a plurality of first unprocessed wafers in the first loadlock chamber, and a plurality of first in-process wafers, the plurality of first in-process wafers being removed from the first loadlock chamber and transferred the first process chamber, the plurality of second wafers include a plurality of second unprocessed wafers in the second loadlock chamber, and a plurality of second in-process wafers, the plurality of second in-process wafers being removed from the second loadlock chamber and transferred to the second process chamber, based on a number of the plurality of first unprocessed wafers being smaller than or equal to a preset value, the controller is configured to initiate cleaning of the first process chamber after completion of the first semiconductor process on both the plurality of first unprocessed wafers and the plurality of first in-process wafers, and based on the number of the plurality of first unprocessed wafers being greater than the preset value, the controller is configured to initiate cleaning of the first process chamber after completion of the first semiconductor process on only the plurality of first in-process wafers.

According to an aspect of an example embodiment, a substrate processing system may include a first loadlock chamber configured to receive a first FOUP that stores a plurality of first wafers, a second loadlock chamber configured to receive a second FOUP that stores a plurality of second wafers, a first process chamber in which a first semiconductor process is configured to be performed on the plurality of first wafers and the plurality of second wafers, a second process chamber in which a second semiconductor process is configured to be performed on the plurality of first wafers and the plurality of second wafers, a transfer robot configured to transfer the plurality of first wafers and the plurality of second wafers to each of the first process chamber and the second process chamber, and a controller configured to determine a number of the plurality of first wafers in the first loadlock chamber and a number of the plurality of second wafers in the second loadlock chamber, and control cleaning of the first process chamber and the second process chamber based on the determined number of the plurality of first wafers and the determined number of the plurality of second wafers, where the plurality of first wafers include a plurality of first unprocessed wafers disposed in the first loadlock chamber, and a plurality of first in-process wafers, the plurality of first in-process wafers being removed from the first loadlock chamber and transferred to the first process chamber or the second process chamber, the plurality of second wafers include a plurality of second unprocessed wafers in the second loadlock chamber, and a plurality of second in-process wafers, the plurality of second in-process wafers being removed from the second loadlock chamber and transferred to the first process chamber or the second process chamber, based on a sum of a number of the plurality of first unprocessed wafers and a number of the plurality of second unprocessed wafers being smaller than or equal to a preset value, the controller is configured to initiate cleaning of the first process chamber and the second process chamber after completion of semiconductor processes on the plurality of first unprocessed wafers, the plurality of first in-process wafers, the plurality of second unprocessed wafers, and the plurality of second in-process wafers, and based on the sum of the number of the plurality of first unprocessed wafers and the number of the plurality of second unprocessed wafers being greater than the preset value, the controller is configured to initiate cleaning of the first process chamber and the second process chamber after completion of semiconductor processes on only the plurality of first in-process wafers and the plurality of second in-process wafers.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a substrate processing system according to one or more embodiments;

FIG. 2 is a diagram illustrating an alignment chamber according to one or more embodiments;

FIG. 3 is a diagram illustrating a wafer disposed on an alignment chamber according to one or more embodiments;

FIG. 4 is a diagram illustrating a first process chamber according to one or more embodiments;

FIG. 5 is a flowchart illustrating a method for operating a substrate processing system according to one or more embodiments;

FIGS. 6 to 13 are diagrams illustrating a method for operating a substrate processing system according to one or more embodiments;

FIG. 14 is a flowchart illustrating a method for operating a substrate processing system according to further one or more embodiments; and

FIGS. 15 to 21 are diagrams illustrating a method for operating the substrate processing system according to further one or more embodiments of the present disclosure.

### DETAILED DESCRIPTIONS

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

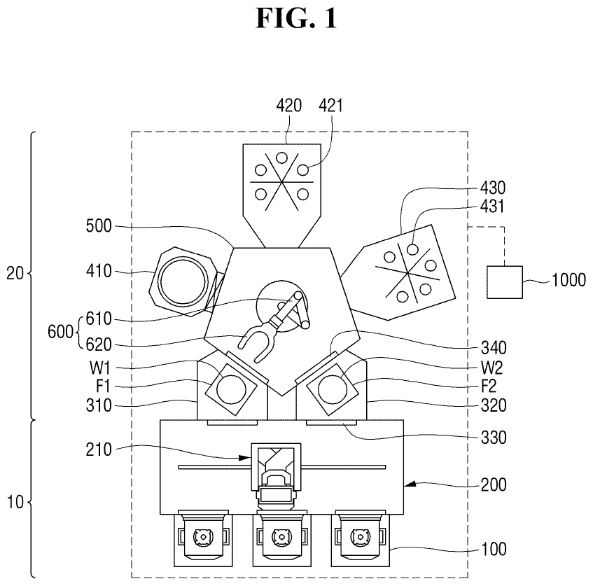

Hereinafter, with reference to FIGS. 1 to 4, a substrate processing system according to one or more embodiments is described.

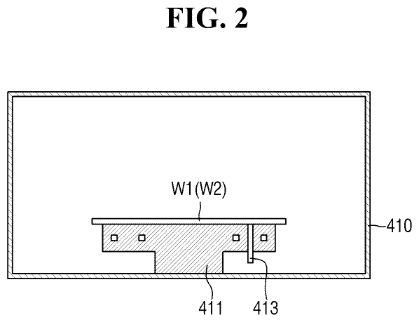

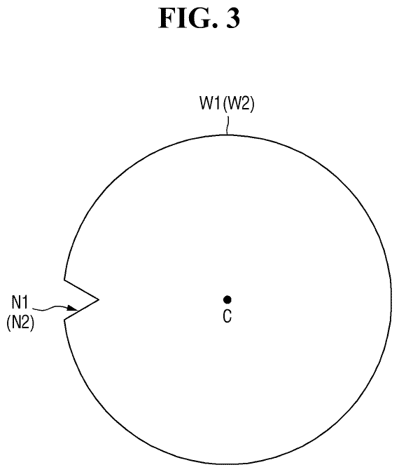

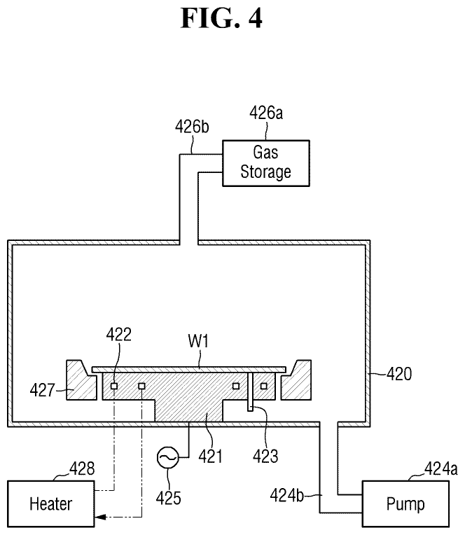

FIG. 1 is a plan view illustrating a substrate processing system according to one or more embodiments. FIG. 2 is a diagram illustrating an alignment chamber according to one or more embodiments. FIG. 3 is a diagram illustrating a wafer disposed on an alignment chamber according to one or more embodiments. FIG. 4 is a diagram illustrating a first process chamber according to one or more embodiments.

Referring to FIGS. 1 to 4, a substrate processing system according to one or more embodiments may include an equipment front end module 10 and a process module 20. The equipment front end module 10 may be disposed on one side of the process module 20. For example, the equipment front end module 10 may be disposed in front of the process module 20. The equipment front end module 10 may include a plurality of load ports 100 and an index module 200. The process module 20 may include a first loadlock chamber 310, a second loadlock chamber 320, an alignment chamber 410, a first process chamber 420, a second process chamber 430, a transfer chamber 500, and transfer robot 600.

The index module 200 may be disposed between the load port 100 and the process module 20. The index module 200 may transfer wafers W1 and W2 between the load port 100 and the process module 20. Each load port 100 may provide a space where a front opening unified pod (FOUP) containing the wafers W1 and W2 is disposed. The index module 200 may include an index robot 210. The index robot 210 may remove the wafers W1 and W2 before processing from the FOUP disposed in the load port 100 and transfer the wafers to the process module 20. Furthermore, the index robot 210 may place the wafers W1 and W2 processed from the process module 20 into the FOUP.

The process module 20 may include the first loadlock chamber 310, the second loadlock chamber 320, the alignment chamber 410, the first process chamber 420, the second process chamber 430, and the transfer chamber 500. The transfer chamber 500 may have a polygonal shape in a plan view. The first and second loadlock chambers 310 and 320, the alignment chambers 410, and the first and second process chambers 420 and 430 may be respectively arranged on edges of the transfer chamber 500. The first and second loadlock chambers 310 and 320 may be disposed on the edge closest to the equipment front end module 10 among the edges of the transfer chamber 500.

For example, the transfer chamber 500 may have a pentagonal shape in a plan view. The transfer chamber 500 may have five side edges. The two process chambers 420 and 430, the two loadlock chambers 310 and 320, and one alignment chamber 410 may be arranged on the side edges thereof, respectively. However, embodiments are not limited thereto. The shape of the transfer chamber 500 and the type and number of the chambers arranged adjacent to the transfer chamber 500 may vary.

The first loadlock chamber 310 may be a space holding a first FOUP F1 in which a plurality of first wafers W1 are stored. The first loadlock chamber 310 may provide a space to temporarily store therein the plurality of first wafers W1 inserted into or removed from the process module 20. An inner space of the first loadlock chamber 310 may be switchable between vacuum and atmospheric pressure. Accordingly, an inner space of each of the transfer chamber 500, the alignment chamber 410, the first process chamber 420, and the second process chamber 430 may be maintained in a vacuum, while an inner space of the equipment front end module 10 may be maintained at atmospheric pressure.

Likewise, the second loadlock chamber 320 may be a space holding a second FOUP F2 in which a plurality of second wafers W2 are stored. The second loadlock chamber 320 may provide a space to temporarily store therein the plurality of second wafers W2 inserted into or removed from the process module 20. An inner space of the second loadlock chamber 320 may be switchable between vacuum and atmospheric pressure. Accordingly, an inner space of each of the transfer chamber 500, the alignment chamber 410, the first process chamber 420, and the second process chamber 430 may be maintained in a vacuum, while an inner space of the equipment front end module 10 may be maintained at atmospheric pressure.

A first gate valve 330 may be installed between each of the first and second loadlock chambers 310 and 320 and the equipment front end module 10. A second gate valve 340 may be installed between each of the first and second loadlock chambers 310 and 320 and the transfer chamber 500. Only one of the first gate valve 330 and the second gate valve 340 may be open to maintain the inner space of each of the transfer chamber 500, the alignment chamber 410, the first process chamber 420, and the second process chamber 430 in a vacuum state.

The transfer robot 600 may be disposed inside the transfer chamber 500. The transfer robot 600 may transfer the plurality of first wafers W1 between the first loadlock chamber 310 and the alignment chamber 410, or between the first loadlock chamber 310 and the first and second process chambers 420 and 430. Furthermore, the transfer robot 600 may transfer the plurality of second wafers W2 between the second loadlock chamber 320 and the alignment chamber 410, or between the second loadlock chamber 320 and the first and second process chambers 420 and 430.

The transfer robot 600 may include a robot arm 610 and a robot hand 620. The robot hand 620 may grip the plurality of first wafers W1 and/or the plurality of second wafers W2. The robot arm 610 may move in an x-axis, y-axis, and z-axis.

The alignment chamber 410 may align the plurality of wafers W1 and W2 so that the plurality of wafers W1 and W2 are oriented in the same direction before the plurality of wafers W1 and W2 are loaded into the process chambers 420 and 430.

For example, in FIG. 2, an alignment support 411 and an alignment lift pin 413 may be disposed inside the alignment chamber 410.

The alignment support 411 may include an electrostatic chuck configured to support the first and second wafers W1 and W2 thereon with an electro-static force, and a chuck support for supporting the electrostatic chuck. The chuck support may support the electrostatic chuck disposed thereon and may be made of a metal such as aluminum or a ceramic insulator such as alumina. The configuration of the alignment support 411 is not limited thereto. The alignment support 411 may include a vacuum chuck configured to support the first and second wafers W1 and W2 using a vacuum. Alternatively, the alignment support 411 may be configured to mechanically support the first and second wafers W1 and W2.

The alignment lift pin 413 may be configured to lift the first and second wafers W1 and W2 from a surface of the alignment support 411 on which the first and second wafers W1 and W2 are seated.

When the first and second wafers W1 and W2 are brought into the alignment chamber 410 or the first and second wafers W1 and W2 are taken out of the alignment chamber 410, the alignment lift pin 413 may be brought into a pin-up state in which the pin protrudes upward beyond the alignment support 411 so as to support the first and second wafers W1 and W2. Furthermore, while the substrate is being processed in the alignment chamber 410, the alignment lift pin 413 may be brought into a pin-down state in which the pin is lowered to a position under an upper surface of the alignment support 411 such that the first and second wafers W1 and W2 may be disposed on the alignment support 411.

The first and second wafers W1 and W2 may be oriented to face in the same direction while being disposed on the alignment support 411.

For example, in FIG. 3, the first and second wafers W1 and W2 may include a first notch N1 and a second notch N2, respectively. The first notch N1 may be provided to align the first wafer W1 with the alignment support 411. The first notch N1 may be disposed at an edge area of the first wafer W1. The first notch N1 may be formed to have a predetermined depth in a direction from an outer edge of the first wafer W1 toward a center C thereof. The second notch N2 may be provided to align the second wafer W2 with the alignment support 411. The second notch N2 may be disposed at an edge area of the second wafer W2. The second notch N2 may be formed to have a predetermined depth in a direction from an outer edge of the second wafer W2 toward a center C thereof.

In one or more embodiments, each of the first notch N1 and the second notch N2 may be oriented to face in the 9 o'clock (i.e., west) direction.

Referring to FIG. 1, the first and second process chambers 420 and 430 may perform processes for processing the first and second wafers W1 and W2, respectively. The semiconductor processes may be respectively performed on the first and second wafers W1 and W2 within the first and second process chambers 420 and 430. Each of the first and second process chambers 420 and 430 may include a processing space therein. The semiconductor process may include at least one of an etching process, a development process, and a deposition process. For example, the semiconductor process may include a chemical vapor deposition (CVD) process. However, embodiments are not limited thereto.

A plurality of first substrate supports 421 may be disposed within the first process chamber 420. For example, five first substrate supports 421 may be disposed in the first process chamber 420. A semiconductor process may be performed simultaneously on at least one wafer within the first process chamber 420. For example, a semiconductor process may be performed simultaneously on five wafers within the first process chamber 420.

Likewise, a plurality of second substrate supports 431 may be disposed within the second process chamber 430. For example, five second substrate supports 431 may be disposed in the second process chamber 430. A semiconductor process may be performed simultaneously on at least one wafer within the second process chamber 430. For example, a semiconductor process may be performed simultaneously on five wafers within the second process chamber 430.

Since the first process chamber 420 and the second process chamber 430 may be substantially identical with each other, only the first process chamber 420 will be described in detail below.

In FIG. 4, within the first process chamber 420, the first substrate support 421 may be disposed. The first substrate support 421 may be disposed under the first process chamber 420. The first wafer W1 may be disposed on the first substrate support 421. The second wafer W2 may be disposed on the first substrate support 421. That is, a semiconductor process may be performed on the first wafer W1 within the first process chamber 420, and a semiconductor process may be performed on the second wafer W2 within the first process chamber 420.

The first substrate support 421 may include an electrostatic chuck configured to support the first wafer W1 thereon with the electro-static force, and a chuck support for supporting the electrostatic chuck thereon. The electrostatic chuck may receive therein an electrode for chucking and de-chucking the substrate. The chuck support may support the electrostatic chuck disposed on a top thereof and may be made of a metal such as aluminum or a ceramic insulator such as alumina. A heating member such as a heater may be disposed inside the chuck support, and heat from the heater may be transferred to the electrostatic chuck or the first wafer W1. Furthermore, a power application wiring connected to the electrode of the electrostatic chuck may be disposed in the chuck support. The configuration of the first substrate support 421 is not limited thereto, and the first substrate support 421 may be configured to include a vacuum chuck configured to support the first wafer W1 using a vacuum, or may be configured to mechanically support the substrate.

The first substrate support 421 may include a first lift pin 423. The first lift pin 423 may be configured to lift the first wafer W1 from a surface of the first substrate support 421 on which the first wafer W1 is mounted. The first lift pin 423 may be accommodated in a hole provided in the first substrate support 421. The first lift pin 423 may be installed to be movable in a vertical direction with respect to the first substrate support 421. The first lift pin 423 may move in the vertical direction to raise and lower the first wafer W1. The first substrate support 421 may include the number of first lift pins 423 suitable for supporting the first wafer W1. For example, the first substrate support 421 may include three or more first lift pins 423 evenly spaced from each other along a circumferential direction of the first substrate support 421. However, embodiments are limited thereto.

When the first wafer W1 is inserted into or removed from the first process chamber 420, the first lift pin 423 may be brought into a pin-up state that the pin protrudes upward beyond the first substrate support 421 to support the first wafer W1. Furthermore, while the first wafer W1 is processed in the first process chamber 420, the first lift pin 423 may be brought into a pin-down state in which the pin is lowered to a position under an upper surface of the first substrate support 421 so that the first wafer W1 is disposed on the first substrate support 421.

An RF bias source 425 may be connected to the first substrate support 421. The RF bias source 425 may apply RF power to the first substrate support 421. In one or more embodiments, the RF bias source 424 may apply the RF power of low frequency lower than about 200 kHz to the substrate support 421 while the cleaning process, the deposition process, the ashing process, and/or the etching process on the first wafer W1 is in progress. In one or more embodiments, the RF bias source 425 may remove the RF power supplied to the first substrate support 421 while the cleaning process, the deposition process, the ashing process, and/or the etching process on the substrate is in progress.

In one or more embodiments, the first substrate support 421 may further include a heating member 422.

The heating member 422 may be connected to the heater 428. The heater 428 may heat the first substrate support 421. The heater 428 may supply heat to the heating member 422 of the first substrate support 421. The heater 428 may control an amount of the heat supplied through the heating member 422 to control a temperature of the first substrate support 421 and a temperature of the first wafer W1 mounted on the first substrate support 421.

The edge ring 427 may disposed along an edge of the first substrate support 421. The edge ring 427 may be disposed on the first substrate support 421. The edge ring 427 may extend to surround the first wafer W1. The edge ring 427 may accurately seat the first wafer W1 and serve as a focus ring to intensively supply gas or plasma to the first wafer W1.

The first process chamber 420 may be connected to a gas storage 426a through a first pipe 426b. When a semiconductor process is performed within the first process chamber 420, the gas stored in the gas storage 426a may be provided into the first process chamber 420 through the first pipe 426b.

The first process chamber 420 may be connected to an exhaust pump 424a through a second pipe 424b. By-products after the semiconductor process may be discharged through the second pipe 424b using the exhaust pump 424a. Furthermore, the exhaust pump 424a may perform the function of controlling the pressure inside the first process chamber 420.

Referring to FIG. 1, the controller 1000 may control the transfer chamber 500, the first and second loadlock chambers 310 and 320, the alignment chamber 410, the first and second process chambers 420 and 430, and the transfer robot 600. Furthermore, the controller 1000 may control (i.e., initiate) cleaning the first and second process chambers 420 and 430. The controller 1000 may determine the number of wafers disposed in the first and second loadlock chambers 310 and 320.

In one or more embodiments, when a semiconductor process is performed within the first and second process chambers 420 and 430, by-products may accumulate within the first and second process chambers 420 and 430. When the by-products accumulate in the first and second process chambers 420 and 430, the by-products may affect the semiconductor process to be performed later. Therefore, the first and second process chambers 420 and 430 should be periodically cleaned to remove the by-products accumulated in the first and second process chambers 420 and 430.

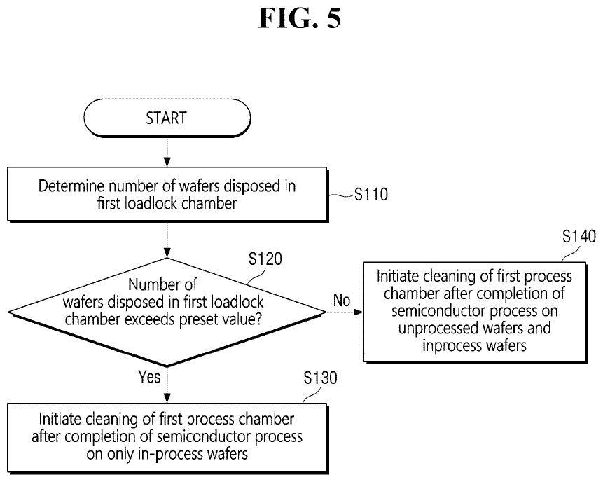

The controller 1000 may control a timing of cleaning the first and second process chambers 420 and 430. This will be described in detail later with reference to FIGS. 5 to 21.

Hereinafter, a method for operating the substrate processing system according to one or more embodiments is described in detail with reference to FIGS. 5 to 21.

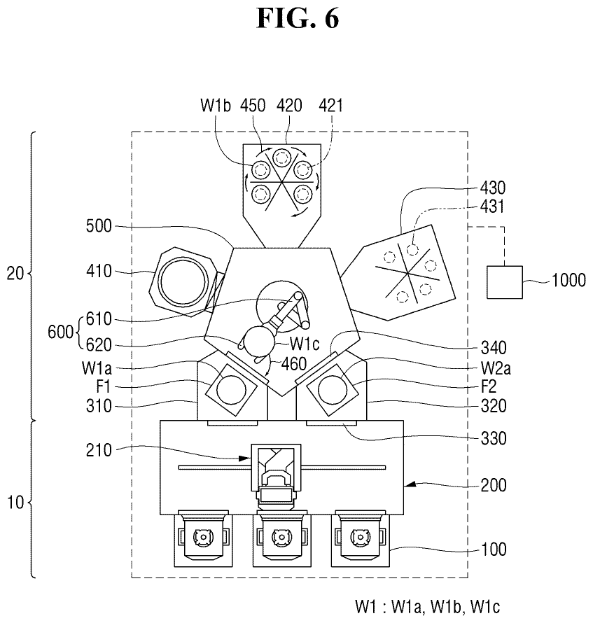

FIG. 5 is a flowchart illustrating a method for operating a substrate processing system according to one or more embodiments. FIGS. 6 to 13 are diagrams illustrating a method for operating a substrate processing system according to one or more embodiments.

In FIG. 5, the operating method of the substrate processing system according to one or more embodiments may include determining the number of wafers disposed in the first loadlock chamber in operation S110, and determining whether the number of wafers disposed in the first loadlock chamber exceeds a preset value in operation S120. Based on the number of wafers disposed in the first loadlock chamber exceeding the preset value, in operation S130, the system may initiate cleaning of the first process chamber after completion of the semiconductor process on only in-process wafers of wafers disposed in the first loadlock chamber. In operation S140, based on the number of wafers disposed in the first loadlock chamber being less than or equal to the preset value, the system may initiate cleaning of the first process chamber after completion of the semiconductor process on unprocessed wafers of wafers disposed in the first loadlock chamber and in-process wafers of wafers disposed in the first loadlock chamber. The controller 1000 may control the process.

Specifically, referring to FIG. 6, the first FOUP F1 may be disposed in the first loadlock chamber 310. A plurality of first wafers W1 may be disposed in the first FOUP F1. Specifically, a plurality of first unprocessed wafers W1a may be disposed in the first loadlock chamber 310. As used herein, the term “unprocessed wafers” may refer to wafers before the semiconductor processing is performed on the wafer.

The second FOUP F2 may be disposed in the second loadlock chamber 320. A plurality of second wafers may be arranged within the second FOUP F2. Specifically, the plurality of second unprocessed wafers W2a may be disposed in the second loadlock chamber 320. Alternatively, the FOUP and wafer may not be disposed in the second loadlock chamber 320.

A semiconductor process may be performed on the plurality of first wafers W1 within the first process chamber 420. Specifically, first in-process wafers W1b may be disposed in the first process chamber 420. A semiconductor process may be performed on at least two or more first in-process wafers W1b within the first process chamber 420. The first in-process wafers W1b may rotate clockwise (direction 450). As used herein, the term “in-process wafers” may refer to wafers on which the semiconductor process is being performed.

The wafer on which all semiconductor processes have been performed may be transferred back to the first loadlock chamber 310 by the transfer robot 600. The wafer on which all semiconductor processes have been performed may be a first processed wafer W1c. That is, the first processed wafer W1c may be exported to the first loadlock chamber 310. As used herein, the term “processed wafer” may refer to a wafer on which a semiconductor process has been performed.

The controller 1000 may determine the number of first unprocessed wafers W1a disposed in the first loadlock chamber 310 in operation S110. The controller 1000 may determine whether the number of first unprocessed wafers W1a exceeds a preset value in operation S120. The preset value may be in a range of 3 to 7. In one or more embodiments, the preset value may be 5. However, embodiments are not limited thereto. The preset value may vary depending on the system.

The number of first unprocessed wafers W1a may be smaller than or equal to the preset value. In this case, the controller 1000 may initiate cleaning of the first process chamber 420 after completion of the semiconductor process on both the first unprocessed wafers W1a and the first in-process wafers W1b.

The number of first unprocessed wafers W1a may be greater than the preset value. In this case, the controller 1000 may initiate cleaning of the first process chamber 420 after completion of the semiconductor process on only the first in-process wafers W1b currently being processed.

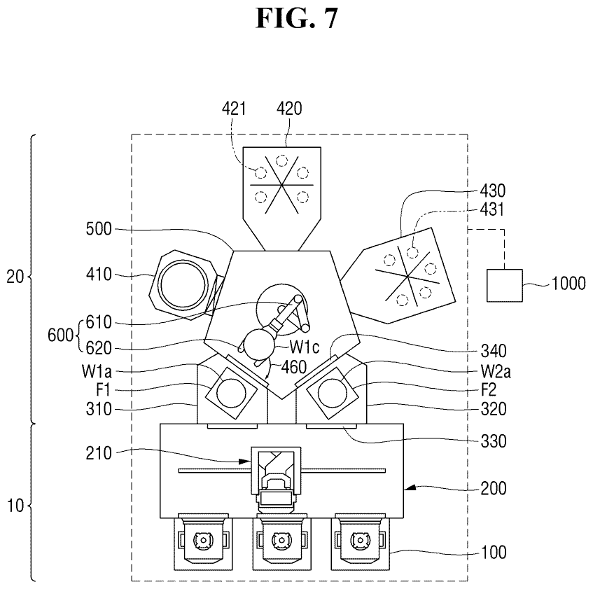

Referring to FIG. 7, when the number of first unprocessed wafers W1a is greater than the preset value, the first unprocessed wafers W1a disposed in the first loadlock chamber 310 are not transferred to the first process chamber 420 via the transfer robot 600. Thus, the semiconductor process may be completed on the first in-process wafers W1b being processed in the first process chamber 420. When the last processed wafer W1c is delivered to the first loadlock chamber 310 (460), the first process chamber 420 may be cleaned.

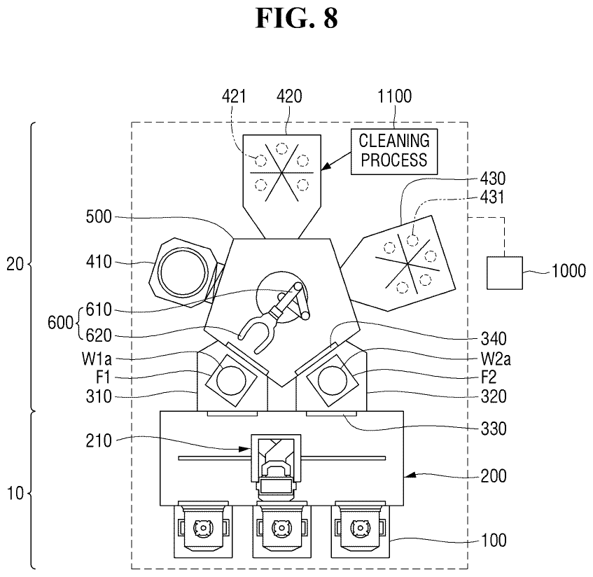

Referring to FIG. 8, the first process chamber 420 may be cleaned (1100). While the first process chamber 420 is being cleaned, the first unprocessed wafers W1a may be disposed in the first loadlock chamber 310. The number of first unprocessed wafers W1a disposed in the first loadlock chamber 310 may be greater than the preset value.

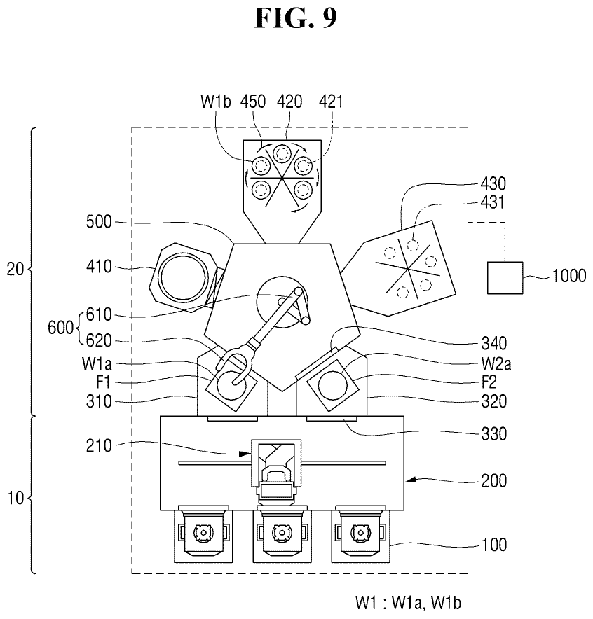

Referring to FIG. 9, when the number of first unprocessed wafers W1a is smaller than or equal to the preset value, the transfer robot 600 may grip the first unprocessed wafers W1a disposed in the first loadlock chamber 310 and may load the same into the first process chamber 420.

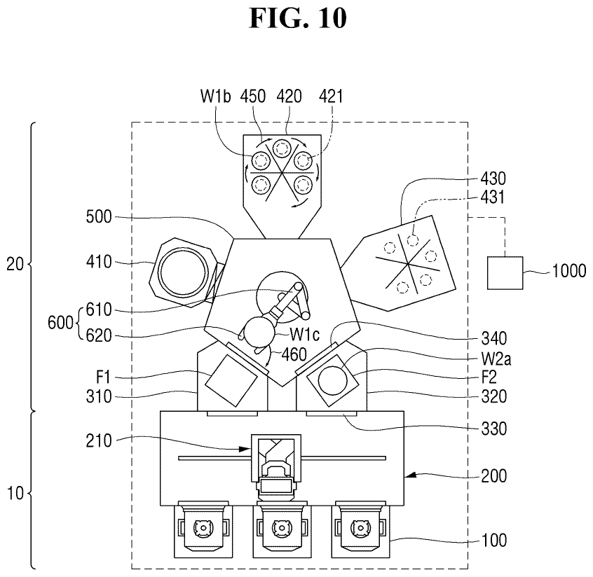

Referring to FIG. 10, first unprocessed wafers W1a disposed in the first loadlock chamber 310 may be loaded into the first process chamber 420, and no wafers may remain in the first loadlock chamber 310.

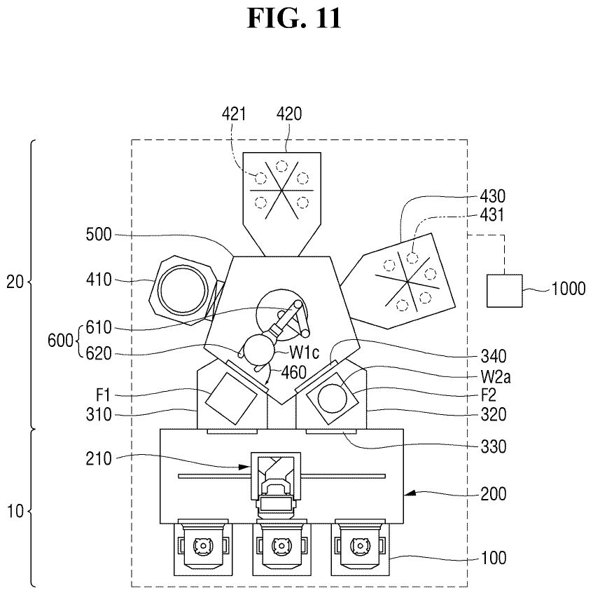

Referring to FIG. 11, the semiconductor process may be completed on the first in-process wafers W1b being processed in the first process chamber 420. When the last processed wafer W1c is delivered to the first loadlock chamber 310 (460), the first process chamber 420 may be cleaned.

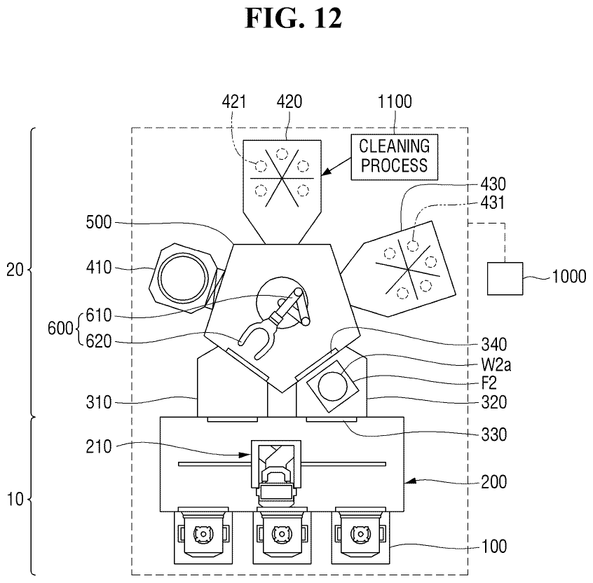

Referring to FIG. 12, the first process chamber 420 may be cleaned (1100). While the first process chamber 420 is being cleaned, the first unprocessed wafers W1a are not disposed in the first loadlock chamber 310.

In this way, the controller 1000 may determine when to clean the first process chamber 420 based on the determined number of wafers disposed in the first loadlock chamber 310. When the number of wafers to be processed is large, the first process chamber 420 may be cleaned as quickly as possible. When the number of wafers to be processed is small, the first process chamber 420 may be cleaned after all remaining wafers have been processed. Accordingly, the substrate processing system with improved efficiency and improved performance may be provided.

As previously described, the preset value may be between 3 and 7. When the preset value is smaller than 3, the process chamber may be cleaned first, even though a small number of wafers remain in the loadlock chamber. In this case, the efficiency of performing the semiconductor process may be reduced. When the preset value is greater than 7, the process chamber may be cleaned after all semiconductor processes on many wafers have been performed, even though many wafers remain. In this case, the by-products accumulated in the process chamber may affect the semiconductor process to be performed later.

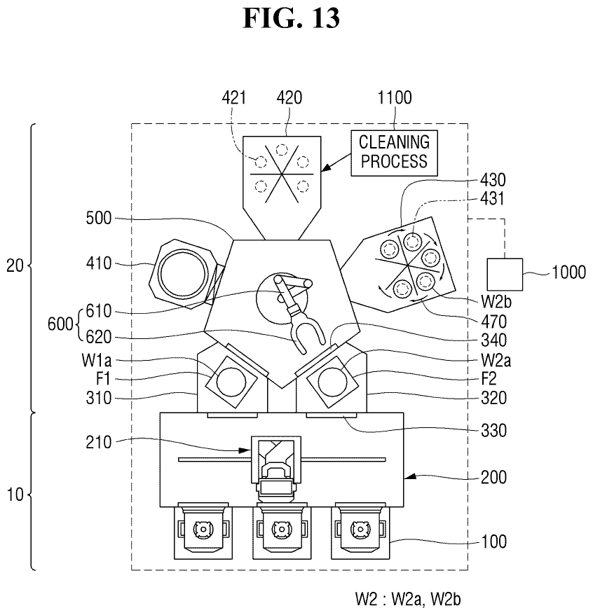

Referring to FIG. 13, while the first process chamber 420 is being cleaned (se1100), the semiconductor process may be performed within the second process chamber 430. That is, the first process chamber 420 and the second process chamber 430 may operates independently.

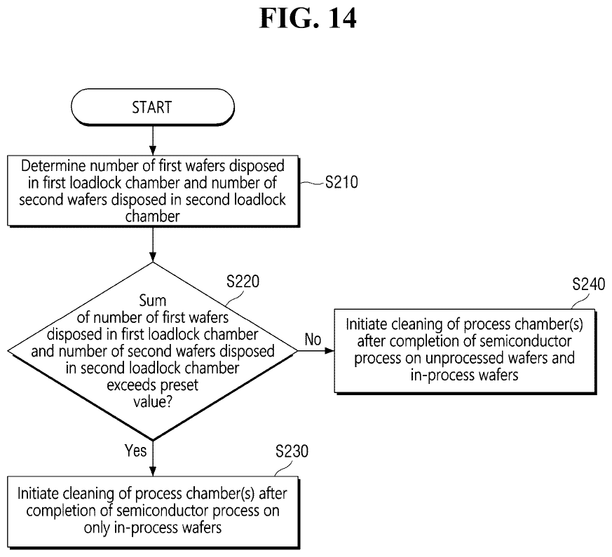

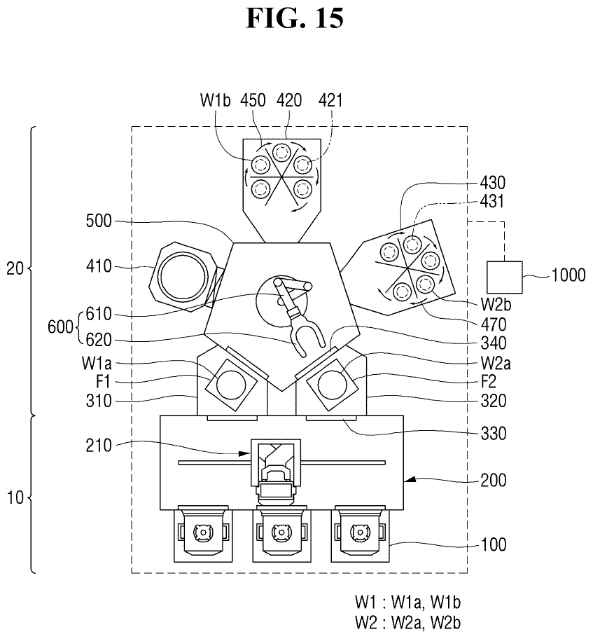

FIG. 14 is a flowchart illustrating a method for operating a substrate processing system according to further one or more embodiments. FIGS. 15 to 21 are diagrams illustrating a method for operating the substrate processing system according to further one or more embodiments of the present disclosure.

Referring to FIG. 14, the operating method of the substrate processing system according to one or more embodiments may include determining the number of first wafers disposed in the first loadlock chamber and the number of second wafers disposed in the second loadlock chamber in operation S210 and determining whether a sum of the number of first wafers disposed in the first loadlock chamber and the number of second wafers disposed in the second loadlock chamber exceeds a preset value in operation S220. Based on the sum of the number of first wafers disposed in the first loadlock chamber and the number of second wafers disposed in the second loadlock chamber exceeding the preset value, in operation S230, the system may initiate cleaning of the process chamber (e.g., the first process chamber and/or the second process chamber) after completion of semiconductor processes on only in-process wafers of the wafers disposed in the first loadlock chamber and in the second loadlock chamber. Based on the sum of the number of first wafers disposed in the first loadlock chamber and the number of second wafers disposed in the second loadlock chamber being less than or equal to the preset value, in operation S240, the system may initiate cleaning of the process chamber (e.g., the first process chamber and/or the second process chamber) after completion of semiconductor processes on both unprocessed wafers and in-process wafers of the wafers disposed in the first loadlock chamber and in the second loadlock chamber. The controller 1000 may control the process.

Specifically, referring to FIG. 15, the first FOUP F1 may be disposed in the first loadlock chamber 310. The plurality of first wafers may be disposed within the first FOUP F1. Specifically, the plurality of first unprocessed wafers W1a may be disposed in the first loadlock chamber 310.

The second FOUP F2 may be disposed in the second loadlock chamber 320. The plurality of second wafers may be arranged within the second FOUP F2. Specifically, the plurality of second unprocessed wafers W2a may be disposed in the second loadlock chamber 320.

A semiconductor process may be performed on the plurality of first wafers W1 within the first process chamber 420. Specifically, the first in-process wafers W1b may be disposed in the first process chamber 420. A semiconductor process may be performed on at least two or more first in-process wafers W1b within the first process chamber 420. The first in-process wafers W1b may rotate clockwise (450).

A semiconductor process may be performed on the plurality of second wafers W2 within the second process chamber 430. Specifically, the second in-process wafers W2b may be disposed in the second process chamber 430. A semiconductor process may be performed on at least two or more second in-process wafers W2b within the second process chamber 430. The second in-process wafers W2b may rotate clockwise (470).

Alternatively, a semiconductor process may be performed on the plurality of second wafers W2 within the first process chamber 420. The semiconductor process may be performed on the plurality of first wafers W1 within the second process chamber 430. That is, the first unprocessed wafers W1a disposed in the first loadlock chamber 310 may be loaded into the second process chamber 430, and the second unprocessed wafers W12 disposed in the second loadlock chamber 320 may be loaded into the first process chamber 420. Hereinafter, for convenience of description, an example is described in which the first wafer W1 is loaded into the first process chamber 420, and the second wafer W2 is loaded into the second process chamber 430.

The first wafer W1 on which all semiconductor processes have been performed may be transferred to the first loadlock chamber 310 by the transfer robot 600. The first wafer on which all semiconductor processes have been performed may be a first processed wafer. That is, the first processed wafer may be transferred to the first loadlock chamber 310. The second wafer W2 on which all semiconductor processes have been performed may be transferred to the second loadlock chamber 320 by the transfer robot 600. The second wafer on which all semiconductor processes have been performed may be a second processed wafer. That is, the second processed wafer may be transferred to the second loadlock chamber 320.

The controller 1000 may determine the number of first unprocessed wafers W1a disposed in the first loadlock chamber 310 and the number of second unprocessed wafers W2a disposed in the second loadlock chamber 320 in operation S210. The controller 1000 may determine whether the sum of the number of first unprocessed wafers W1a and the number of second unprocessed wafers W2a exceeds the preset value in operation S220. The preset value may in a range of 3 to 7.

When the sum of the number of first unprocessed wafers W1a and the number of second unprocessed wafers W2a is smaller than or equal to the preset value, the semiconductor process has been performed on all of the first unprocessed wafers W1a, the first in-process wafers W1b, the second unprocessed wafers W2a, and the second in-process wafers W2b, and then, the controller 1000 may initiate cleaning of the first process chamber 420 and the second process chamber 430.

The sum of the number of first unprocessed wafers W1a and the number of second unprocessed wafers W2a may be greater than the preset value. In this case, after the semiconductor process is performed only on the first in-process wafers W1b and the second in-process wafers W2b that are currently being processed, the controller 1000 may initiate cleaning of the first process chamber 420 and the second process chamber 430.

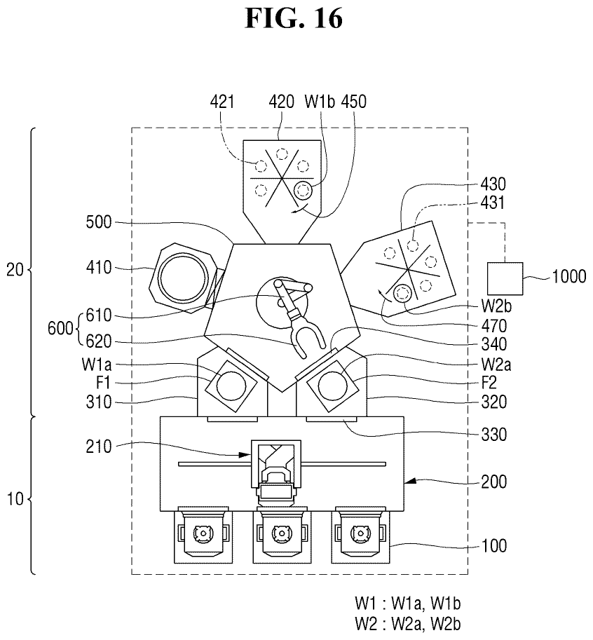

Referring to FIG. 16, when the sum of the number of first unprocessed wafers W1a and the number of second unprocessed wafers W2a is greater than the preset value, the first unprocessed wafers W1a disposed in the first loadlock chamber 310 are not transferred to the first process chamber 420 by the transfer robot 600. The second unprocessed wafers W2a disposed in the second loadlock chamber 320 are not transferred to the second process chamber 430 by the transfer robot 600.

The semiconductor process may be completed on the first in-process wafers W1b being processed in the first process chamber 420. Furthermore, the semiconductor process may be completed on the second in-process wafers W2b being processed in the second process chamber 430.

When the last in-process wafer W1b and the last in-process wafer W2b are transferred to the first loadlock chamber 310 and the second loadlock chamber 320, respectively, the first process chamber 420 and the second process chamber 430 may be cleaned.

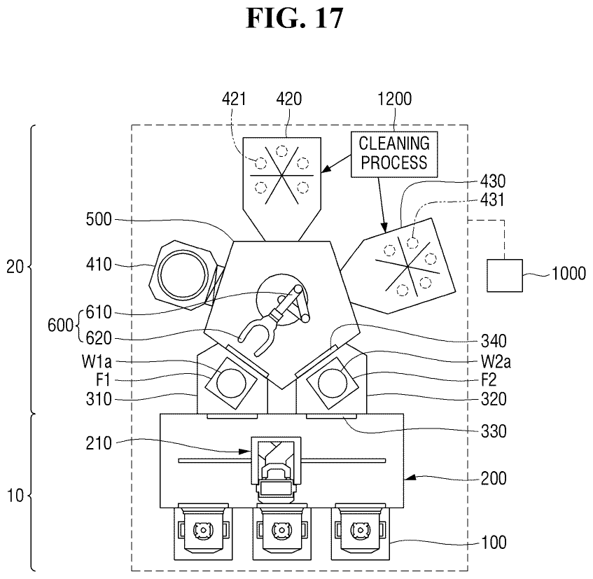

Referring to FIG. 17, both the first process chamber 420 and the second process chamber 430 may be cleaned (1200). While both the first process chamber 420 and the second process chamber 430 are being cleaned, the first unprocessed wafers W1a may be disposed in the first loadlock chamber 310, and the second unprocessed wafers W1b may be disposed in the second loadlock chamber 320. The sum of the number of first unprocessed wafers W1a disposed in the first loadlock chamber 310 and the number of second unprocessed wafers W2a disposed in the second loadlock chamber 320 may be larger than the preset value.

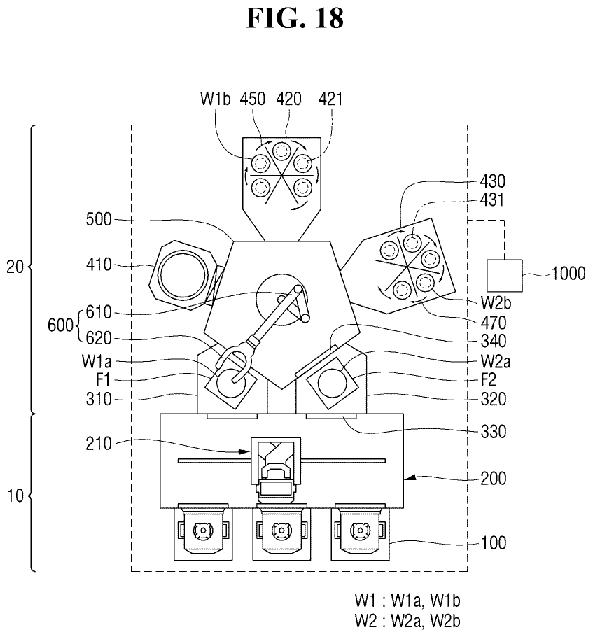

Referring to FIG. 18, when the sum of the number of first unprocessed wafers W1a and the number of second unprocessed wafers W2a is smaller than or equal to the preset value, the transfer robot 600 may grip the first unprocessed wafers W1a disposed in the first loadlock chamber 310 and load the gripped unprocessed wafers W1a into the first process chamber 420. Furthermore, the transfer robot 600 may grip the second unprocessed wafers W2a disposed in the second loadlock chamber 320 and load the gripped unprocessed wafers W2a into the second process chamber 430.

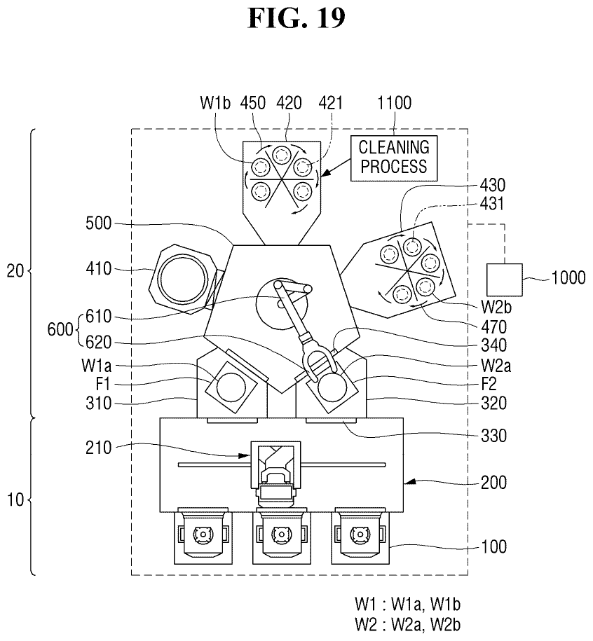

Referring to FIG. 19, all first unprocessed wafers W1a disposed in the first loadlock chamber 310 may be loaded into the first process chamber 420. No wafers may remain in the first loadlock chamber 310. All second unprocessed wafers W2a disposed in the second loadlock chamber 320 may be loaded into the second process chamber 430. There may be no second wafer W2 remaining in the second loadlock chamber 320.

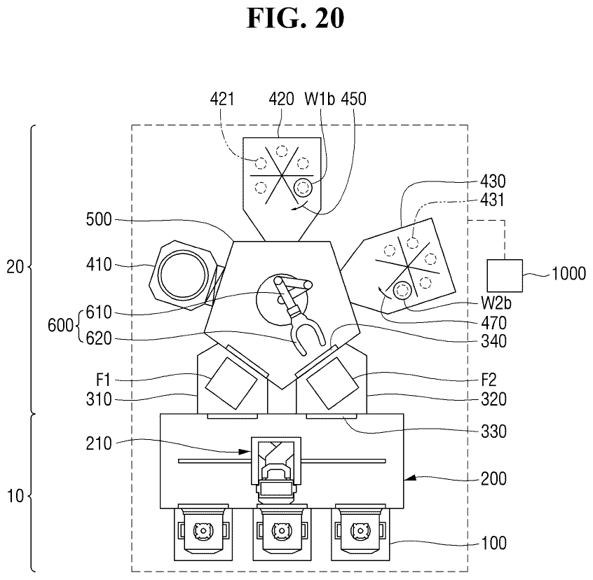

Referring to FIG. 20, the semiconductor process may be completed on the first in-process wafers W1b being processed in the first process chamber 420. Furthermore, the semiconductor process may be completed on the second in-process wafers W2b being processed in the second process chamber 430. When the last in-process wafer W1b and the last in-process wafer W2b are transferred to the first loadlock chamber 310 and the second loadlock chamber 320, respectively, both the first process chamber 420 and the second process chambers 430 may be cleaned.

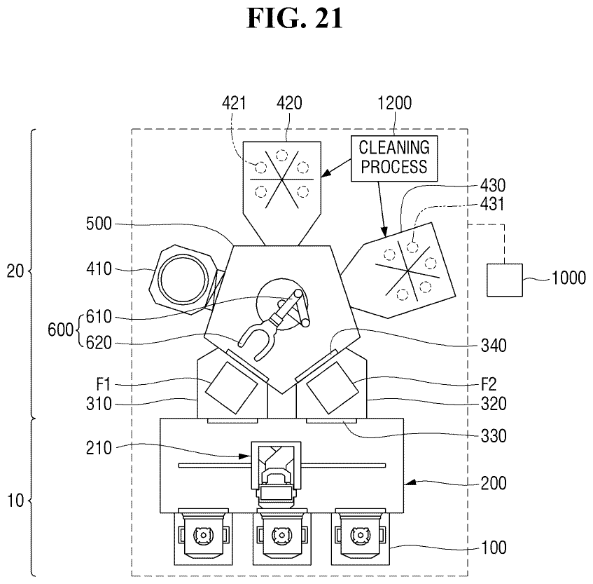

Referring to FIG. 21, both the first process chamber 420 and the second process chamber 430 may be cleaned (1200). While the first process chamber 420 is being cleaned, the first unprocessed wafers W1a are not disposed in the first loadlock chamber 310. While the second process chamber 430 is being cleaned, the second unprocessed wafers W2a are not disposed in the second loadlock chamber 320.

As described with reference to FIGS. 5 to 13, the controller 1000 may control the first process chamber 420 and the second process chamber 430 separately. Alternatively, as described with reference to FIGS. 14 to 21, the controller 1000 may control the first process chamber 420 and the second process chamber 430 together.

In this way, the controller 1000 may determine the number of wafers remaining in the loadlock chamber 310 and 320 and may determine a timing at which the process chamber 420, and 430 are to be cleaned, based on the number of wafers remaining in the loadlock chamber 310 and 320. Thus, the process chambers 420 and 430 may be quickly cleaned when cleaning is necessary, and the process efficiency thereof may be improved. Accordingly, the substrate processing system with improved performance and reliability may be manufactured.

At least one of the devices, units, components, modules, units, or the like represented by a block or an equivalent indication in the above embodiments including, but not limited to, FIGS. 1, 4, 6-13 and 15-21 may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing system comprising:
a loadlock chamber configured to receive a front opening unified pod (FOUP) that stores a plurality of wafers;
a process chamber in which a semiconductor process is configured to be performed on the plurality of wafers;
a transfer robot configured to transfer the plurality of wafers from the loadlock chamber to the process chamber; and
a controller configured to determine a number of the plurality of wafers in the loadlock chamber and control cleaning of the process chamber based on the determined number of the plurality of wafers,
wherein the plurality of wafers comprise a plurality of unprocessed wafers in the loadlock chamber, and a plurality of in-process wafers, the plurality of in-process wafers being removed from the loadlock chamber and transferred to the process chamber,
wherein, based on a number of the plurality of unprocessed wafers being smaller than or equal to a preset value, the controller is configured to initiate cleaning of the process chamber after completion of the semiconductor process on both the plurality of unprocessed wafers and the plurality of in-process wafers, and
wherein, based on the number of the plurality of unprocessed wafers being greater than the preset value, the controller is configured to initiate cleaning of the process chamber after completion of the semiconductor process on only the plurality of in-process wafers.

2. The substrate processing system of claim 1, wherein the preset value is in a range of 3 to 7.

3. The substrate processing system of claim 1, wherein the semiconductor process is performed simultaneously on at least two wafers in the process chamber.

4. The substrate processing system of claim 1, wherein a number of the plurality of wafers in the FOUP is 25 or less.

5. The substrate processing system of claim 1, further comprising an alignment chamber configured to align the plurality of wafers to be oriented in the same direction.

6. The substrate processing system of claim 1, wherein the semiconductor process comprises a chemical vapor deposition (CVD) process.

7. The substrate processing system of claim 1, further comprising a load port connected to the loadlock chamber and configured to store the FOUP,
wherein the FOUP is loaded into or unloaded from the load port while the process chamber is being cleaned.

8. A substrate processing system comprising:
a first loadlock chamber configured to receive a first front opening unified pod (FOUP) that stores a plurality of first wafers;
a first process chamber in which a first semiconductor process is configured to be performed on the plurality of first wafers;
a second loadlock chamber configured to receive a second FOUP that stores a plurality of second wafers;
a second process chamber in which a second semiconductor process is configured to be performed on the plurality of second wafers;
a transfer robot configured to transfer the plurality of first wafers to the first process chamber and transfer the plurality of second wafers to the second process chamber; and
a controller configured to determine a number of the plurality of first wafers in the first loadlock chamber and a number of the plurality of second wafers in the second loadlock chamber, and control cleaning of the first process chamber and the second process chamber based on the determined number of the plurality of first wafers and the determined number of the plurality of second wafers,
wherein the plurality of first wafers comprise a plurality of first unprocessed wafers in the first loadlock chamber, and a plurality of first in-process wafers, the plurality of first in-process wafers being removed from the first loadlock chamber and transferred the first process chamber,
wherein the plurality of second wafers comprise a plurality of second unprocessed wafers in the second loadlock chamber, and a plurality of second in-process wafers, the plurality of second in-process wafers being removed from the second loadlock chamber and transferred to the second process chamber,
wherein, based on a number of the plurality of first unprocessed wafers being smaller than or equal to a preset value, the controller is configured to initiate cleaning of the first process chamber after completion of the first semiconductor process on both the plurality of first unprocessed wafers and the plurality of first in-process wafers, and
wherein, based on the number of the plurality of first unprocessed wafers being greater than the preset value, the controller is configured to initiate cleaning of the first process chamber after completion of the first semiconductor process on only the plurality of first in-process wafers.

9. The substrate processing system of claim 8, wherein, based on a number of the plurality of second unprocessed wafers being smaller than or equal to the preset value, the controller is configured to initiate cleaning of the second process chamber after completion of the second semiconductor process on both the plurality of second unprocessed wafers and the plurality of second in-process wafers,
wherein, based on the number of the plurality of second unprocessed wafers being greater than the preset value, the controller is configured to initiate cleaning of the second process chamber after completion of the second semiconductor process on only the plurality of second in-process wafers.

10. The substrate processing system of claim 8, wherein the preset value is in a range of 3 to 7.

11. The substrate processing system of claim 8, wherein the first semiconductor process and the second semiconductor process are performed simultaneously on at least two wafers in each of the first process chamber and the second process chamber, respectively.

12. The substrate processing system of claim 8, wherein a number of the plurality of first wafers in the first FOUP is 25 or less, and
wherein a number of the plurality of second wafers in the second FOUP is 25 or less.

13. The substrate processing system of claim 8, wherein at least one of the first semiconductor process and the second semiconductor process comprises a chemical vapor deposition (CVD) process.

14. The substrate processing system of claim 8, wherein the second semiconductor process is performed on the plurality of second wafers in the second process chamber while the first process chamber is cleaned.

15. The substrate processing system of claim 8, further comprising:
a first load port connected to the first loadlock chamber and configured to store the first FOUP; and
a second load port connected to the second loadlock chamber and configured to store the second FOUP,
wherein, while the first process chamber is being cleaned, the first FOUP is loaded into or unloaded from the first load port, and the second FOUP is loaded into or unloaded from of the second load port.

16. A substrate processing system comprising:
a first loadlock chamber configured to receive a first front opening unified pod (FOUP) that stores a plurality of first wafers;
a second loadlock chamber configured to receive a second FOUP that stores a plurality of second wafers;
a first process chamber in which a first semiconductor process is configured to be performed on the plurality of first wafers and the plurality of second wafers;
a second process chamber in which a second semiconductor process is configured to be performed on the plurality of first wafers and the plurality of second wafers;
a transfer robot configured to transfer the plurality of first wafers and the plurality of second wafers to each of the first process chamber and the second process chamber; and
a controller configured to determine a number of the plurality of first wafers in the first loadlock chamber and a number of the plurality of second wafers in the second loadlock chamber, and control cleaning of the first process chamber and the second process chamber based on the determined number of the plurality of first wafers and the determined number of the plurality of second wafers,
wherein the plurality of first wafers comprise a plurality of first unprocessed wafers disposed in the first loadlock chamber, and a plurality of first in-process wafers, the plurality of first in-process wafers being removed from the first loadlock chamber and transferred to the first process chamber or the second process chamber,
wherein the plurality of second wafers comprise a plurality of second unprocessed wafers in the second loadlock chamber, and a plurality of second in-process wafers, the plurality of second in-process wafers being removed from the second loadlock chamber and transferred to the first process chamber or the second process chamber,
wherein, based on a sum of a number of the plurality of first unprocessed wafers and a number of the plurality of second unprocessed wafers being smaller than or equal to a preset value, the controller is configured to initiate cleaning of the first process chamber and the second process chamber after completion of semiconductor processes on the plurality of first unprocessed wafers, the plurality of first in-process wafers, the plurality of second unprocessed wafers, and the plurality of second in-process wafers, and
wherein, based on the sum of the number of the plurality of first unprocessed wafers and the number of the plurality of second unprocessed wafers being greater than the preset value, the controller is configured to initiate cleaning of the first process chamber and the second process chamber after completion of semiconductor processes on only the plurality of first in-process wafers and the plurality of second in-process wafers.

17. The substrate processing system of claim 16, wherein the first semiconductor process and the second semiconductor process are performed simultaneously on at least two wafers in each of the first process chamber and the second process chamber.

18. The substrate processing system of claim 16, wherein a number of the plurality of first wafers in the first FOUP is 25 or less, and
wherein a number of the plurality of second wafers in the second FOUP is 25 or less.

19. The substrate processing system of claim 16, wherein at least one of the first semiconductor process and the second semiconductor process comprises a chemical vapor deposition (CVD) process.

20. The substrate processing system of claim 16, further comprising an alignment chamber configured to align the plurality of first wafers to be oriented in the same direction, and align the plurality of second wafers to be oriented in the same direction.
